(19) United States
(12) Patent Application Publication
(10) Pub. No.: US 2013/0030738 A1
(43) Pub. Date: Jan. 31, 2013

(54) Converging algorithm for real-time battery prediction

(71) Applicant: Ioannis Milios, New York, NY (US)

(72) Inventor: Ioannis Milios, New York, NY (US)

(73) Assignee: SENDYNE CORPORATION, New York, NY (US)

(21) Appl. No.: 13/635,427

(22) PCT Filed: Jan. 19, 2012
(86) PCT No.: PCT/IB2012/050270

§ 371 Date: Sep. 28, 2012

Related U.S. Application Data
(60) Provisional application No. 61/434,225, filed on Jan. 19, 2011.

(51) Int. Cl. G01R 31/36; G06F 19/00

(52) U.S. Cl. 702/63

(57) ABSTRACT

A method predicts the battery state in “real-time”, which is based on a nodal algorithmic model. Under this method, the battery is modeled as a network mesh of both linear and non-linear electrical branch elements. Those branch elements are inter-connected through a set of nodes. Each node can have several branches either originating or ending into it. The branch elements may represent loosely some particular function or region of the battery or they may serve a pure algorithmic function. The non-linear behavior of the elements may be described either algorithmically or through lookup tables. Kirchhoff's laws are applied on each node to describe the relationships between currents and voltages. The system may be connected with a battery so that it can receive measured values at the battery, and the system yields state-of-charge, state-of-health, and state-of- function signals.

Gainful utilization of large scale batteries in electric and hybrid cars as well as in other energy storage applications benefits greatly from real time accurate predictions of battery's performance, including determination of current State of Charge (SOC), State of Health (SOH) and State of Function (SOF) (see “Battery Monitoring and Electrical Energy Management Precondition for future vehicle electric power systems”, Eberhard Meissner, Gerolf Richter, Journal of Power Sources 116 (2003) 79-98). It is well understood in the industry that battery state cannot be derived with accuracy, relying solely on direct measurements. Coulomb integration methods suffer from accumulated errors exacerbated in environments characterized by intermittent charging and discharging, such as in the car environment. As an alternative to direct measurement based derivation of the battery state, adaptive algorithms have been proposed such as the Extended Kalman Filter (EKF) (see U.S. Pat. No. 6,441,586, “State of charge prediction method and apparatus for a battery”, Tate Jr.et al, 2002). A Kalman Filter (KF) estimates the state of a linear system using all available information of an underlying model, as well as the noise characterization and all previous observations. The EKF is an extension of the method for non-linear systems.

After the EKF predicts the next state, theoretical calculated data are compared with measurements. The state variables are subsequently corrected in such a way as to minimize the sum of squared errors between the estimated values and the actual values. EKF implementations have been used in the industry achieving SOC prediction accuracy close to 5% (see G. Plett, “Kalman-Filter SOC Estimation for LiPB HEV Cells”, Proceedings of the 19th International Battery, Hybrid and Fuel Cell Electric Vehicle Symposium & Exhibition (EVS19), 19-23 October 2002, Busan, Korea).

Although stochastic methods have shown to improve prediction accuracy, they are limited by the underlying battery models. Methods such as the KF and EKF, although capable of including all available information, are not required to interrelate, crosscheck or combine this information into one consistent model in order to produce results. In addition the “correction” achieved on each cycle is applied upon the filter parameters and not the underlying model itself. As a result, dynamic changes in the operating conditions that either produce incorrect initial state estimates or are not supported sufficiently by the model may cause the filter to diverge. Another problem with the EKF is that the estimated covariance matrix tends to underestimate the true covariance matrix and therefore risks becoming inconsistent, in the statistical sense, without the addition of “stabilizing noise”.

### SUMMARY OF THE INVENTION

This invention proposes a novel method to predict the battery state in “real-time”, which is based on a nodal algorithmic model. Under this method, the battery is modeled as a network mesh of both linear and non-linear electrical branch elements. Those branch elements are interconnected through a set of nodes. Each node can have several branches either originating or ending into it. The branch elements may represent loosely some particular function or region of the battery or they may serve a pure algorithmic function. The non-linear behavior of the elements may be described either algorithmically or through lookup tables. Kirchhoff's laws are applied on each node to describe the relationships between currents and voltages.

For transient analysis, components are represented in differential or integral form. Non-linear elements are solved by an iterative method (e.g. Newton-Raphson) at each time step. An initial guess at the node voltages is created. The slope and intercept of the tangent to the actual I-V curve is used to calculate a linear approximation of the non-linear element. The linear approximation is used as a proxy for the real device. Solution of the linear proxy yields a better guess at the voltage vector. A new set of conductance/current source proxies are calculated using tangents at the new voltages. This is repeated until convergence is reached.

The above generally described method has been used successfully in simulation of integrated electronic circuits. Several EDA programs such as SPICE (see Nagel, L. W, and Pederson, D. O., SPICE (Simulation Program with Integrated Circuit Emphasis), Memorandum No. ERL-M382, University of California, Berkeley, April 1973; see Ho, Ruehli, and Brennan (April 1974). “The Modified Nodal Approach to Network Analysis”. Proc. 1974 Int. Symposium on Circuits and Systems, San Francisco. pp. 505-509, at http://ieeexplore.ieee.org/xpls/abs_all.jsp? arnumber=1084079) are available which demonstrate the success of the methodology in computing complex electrical systems.

Chen and Rincon-Mora (“Accurate Electrical Battery Model Capable of Predicting Runtime and I-V Performance” Min Chen, Gabriel A. Rincon-Mora, IEEE Transactions on Energy Conversion, Vol. 21, No. 2, June 2006) have shown in a simplified implementation that such algorithms applied to a battery model can match both the battery runtime and I-V performance accurately, at least in a limited set of measurements.

The simulation may be carried out by means of electronic circuits constructed for the purpose, thus achieving results much like those of a software-based simulation such as SPICE. Such circuits may be packaged with an actual battery in a real-life usage environment, permitting development of SOC, SOF, and SOH information in real time and with better accuracy than some prior-art approaches.

### DESCRIPTION OF THE DRAWING

The invention will be described with respect to a drawing in several figures, of which:

FIG. 1 shows a basic large battery system configuration;

FIG. 2 shows an adaptive optimization system according to the invention;

FIG. 3 shows a node-based simulation approach according to the invention;

FIG. 4 shows an embodiment of the invention in which the node-based approach is packaged with the battery itself;

FIGS. 5a and 5b show alternatives to the embodiment of FIG. 4; and

FIG. 6 shows a typical battery model.

### DESCRIPTION OF THE INVENTION

The invention will now be described in some detail. The discussion which follows introduces the use of a complete electrical simulation module for predicting battery state, describes prediction of future states, discusses estimation of the quality of such prediction, and characterizes an active adaptation algorithm

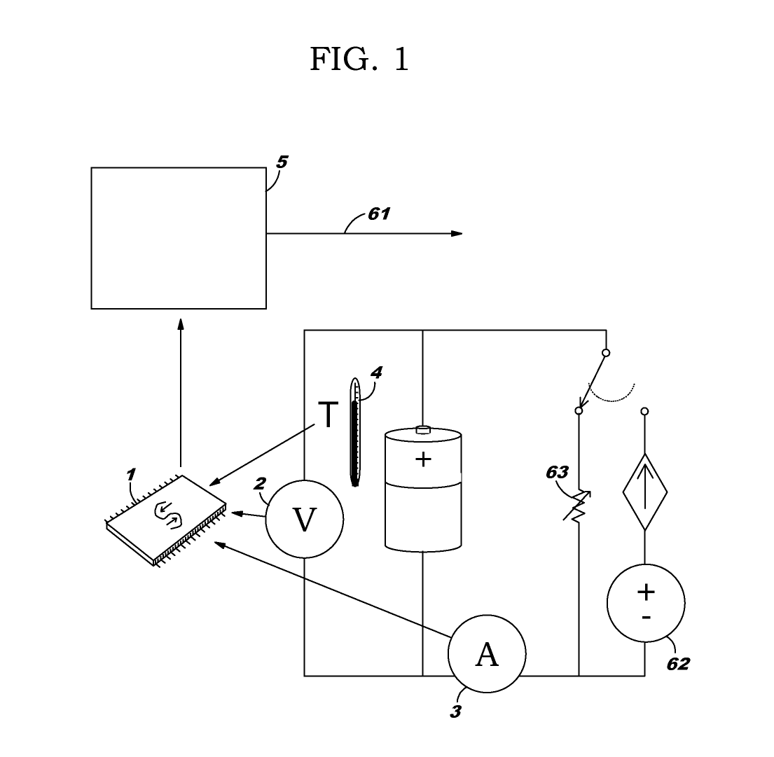

1. Using a Complete Electrical Simulation Module for Predicting the Battery State. FIG. 1 illustrates a basic Large Battery System (LBS). A Battery System Manager 1 is typically a microprocessor and among other things monitors pack and cell voltage V 2, pack current A 3 and cell environment temperatures T 4, both during charging and discharging of the battery. Data collected are fed to a battery modeling algorithm 5 which outputs estimates at 61 for non-measurable data, such as State of Charge (SOC) and State of Health (SOH). In our invention the battery modeling algorithm is a nodal simulation algorithm, like SPICE, where the battery is modeled as a network mesh of both linear and non-linear electrical branch elements. Current, voltage and temperature of the pack are fed as inputs to the algorithm, and SOC, SOH, battery internal impedance, cell heat release and other useful entities describing the current state of the battery are derived as outputs of the algorithm, as described in more detail above. This algorithm, in distinction with the current state of the art, provides an integrated simulation module, combining and interrelating all data in into the same model. (For example the prior-art approach of a Coulomb counting algorithm cannot relate its data with the internal impedance or the battery output voltage.) FIG. 1 depicts generically the notions of load 63 and charging means 62. A typical application would be that of an electric or hybrid automobile in which the load includes a drive train.

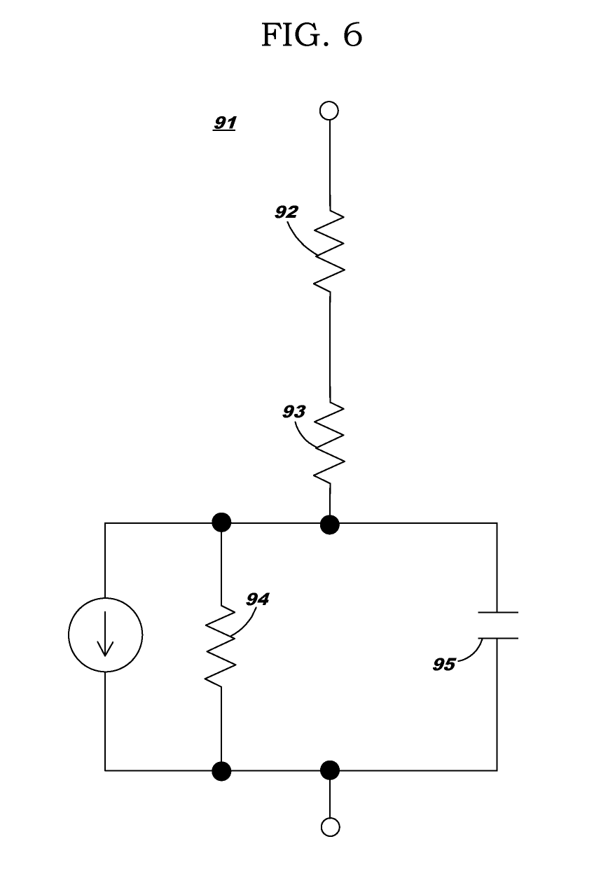

Turning ahead briefly to FIG. 6, what is shown is a typical battery model as might be employed in the battery modeling algorithm of box 5. In this battery model the battery is a two-terminal device, with an effective internal resistance 92, 93, a discharge resistance 94, and a capacitive storage 95. Any of a variety of battery models may be employed without departing in any way from the invention.

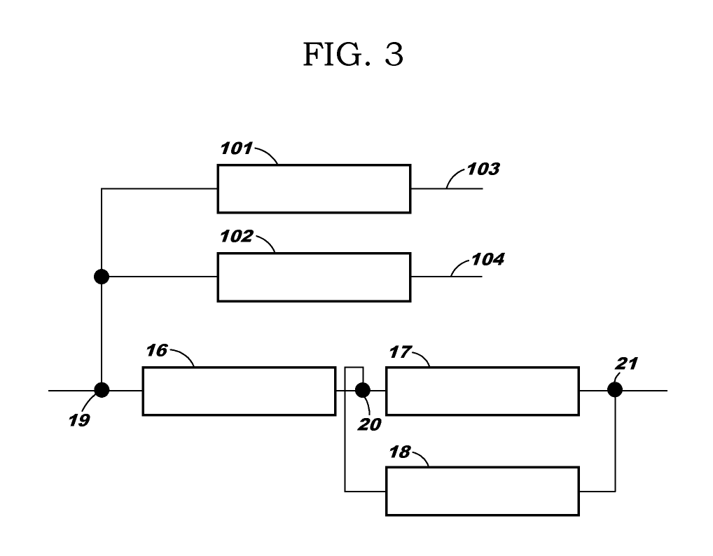

Turning back to FIG. 3, the node-based simulation approach 11 is depicted in some schematic detail. Under this method, the battery is modeled as a network mesh of both linear and non-linear electrical branch elements 16, 17, 18. Those branch elements 16, 17, 18 are interconnected through a set of nodes 19, 20, 21. Each node can have one or more branches either originating or ending into it. In the schematic depiction of FIG. 3, the model is intentionally simplified for clarity. Nodes 19 and 21 each carry a (simulated) voltage deemed to simulate values of measurable quantities. For example in this simplified model the (simulated) voltage at node 21 represents real-world battery output voltage while the (simulated) voltage at node 19 represents real-world battery EMF.

Each branch element 16, 17, 18 may represent loosely some particular function or region of the battery or it may serve a pure algorithmic function. Saying this differently, a branch element (as chosen by the designer of a particular model) may have a goal of simulating some physical phenomenon (e.g. ion diffusion, chemistry-based energy storage), but in some cases it may turn out that a branch element that merely carries out an abstract mathematical calculation or algorithmic function, lacking any particular intended physical meaning, yet may contribute to a simulation that turns out to be more accurate than a simulation carried out without that branch element being present.

While some nodes (19, 21) represent (simulated) real-world measurable values, other nodes 20 carry (simulated) voltages that merely “pass messages” between branch elements. In the simplified depiction of FIG. 3 it is portrayed that branch element 16 and branch elements 17 and 18 are connected by node 20. Such message passing might, for example, represent an output from branch element 16 to node 20, which in turn serves as inputs to branch elements 17 and 18. Such a “message passing” node 20 might be communicating some physically measurable value (e.g. concentration of a particular reaction product in a cell of the battery) that happens not to be readily measurable in real time but forms part of the model. But such a “message passing” node 20 may also communicate merely a mathematical value being passed from one branch element to another, where the passed mathematical value lacks any particular intended physical meaning, but which may contribute to a simulation that turns out to be more accurate than a simulation carried out without that nodal value being communicated.

Non-measurable data, such as State of Charge (SOC), State of Health (SOH), and State of Function (SOF) may be derived with simple calculations by observing node potentials or potential differences. For example the potential of node 19 simulating the real world battery EMF is directly related to the battery SOC, or the difference of potential between nodes 21 and 19 can provide an indication of the battery internal impedance. These are outputs from the model, and as will be appreciated it is the accuracy of these outputs that the system seeks to maximize. As an example in FIG. 3, node 19 serves as an input to a branch element 102 which, together with stored historical data about the battery, develops a SOH value at 104. For example if the present-day battery capacity is notably smaller than the battery capacity when the battery was first placed into service, then the present-day SOH value would be smaller than it was when the battery was first placed into service. As a second example, the value at node 19 may be employed as a direct indication of SOC. As a third example, the value at node 19 serves as an input to a branch element 101 which carries out a “what if” projection of future events given particular assumptions about what might happen next, developing for example an SOF value at 103.

A branch element among the branch elements 16, 17, 18 may be chosen by the model designer as a straightforward linear device, the output or outputs of of which are linearly related to its inputs.

The simulation of such a branch element is easy. Another branch element among the branch elements 16, 17, 18 may be chosen by the model designer to be a non-linear device. The non-linear behavior of such a branch element may be simulated either algorithmically or by means of (for example) a lookup table.

A battery consisting of many cells connected serially and/or in parallel can be simulated either by a single simulation circuit like the one in FIG. 3 or by connecting multiple simulation circuits serially and/or in parallel to resemble the connections of the actual cells.

Once the branch elements 16, 17, 18 and their internal functions are selected, and once the nodal connections are established in the simulator (e.g. SPICE), then simulation may be carried out. The alert reader will appreciate that the circuit simulator (e.g. SPICE) is being used to simulate a circuit 11, which in turn is being used to simulate a physical system. Saying this differently, there are two levels of simulation taking place. In the “lower level” simulation (the circuit simulation), Kirchhoff's laws are applied on each node 15 to describe the relationships between currents and voltages.

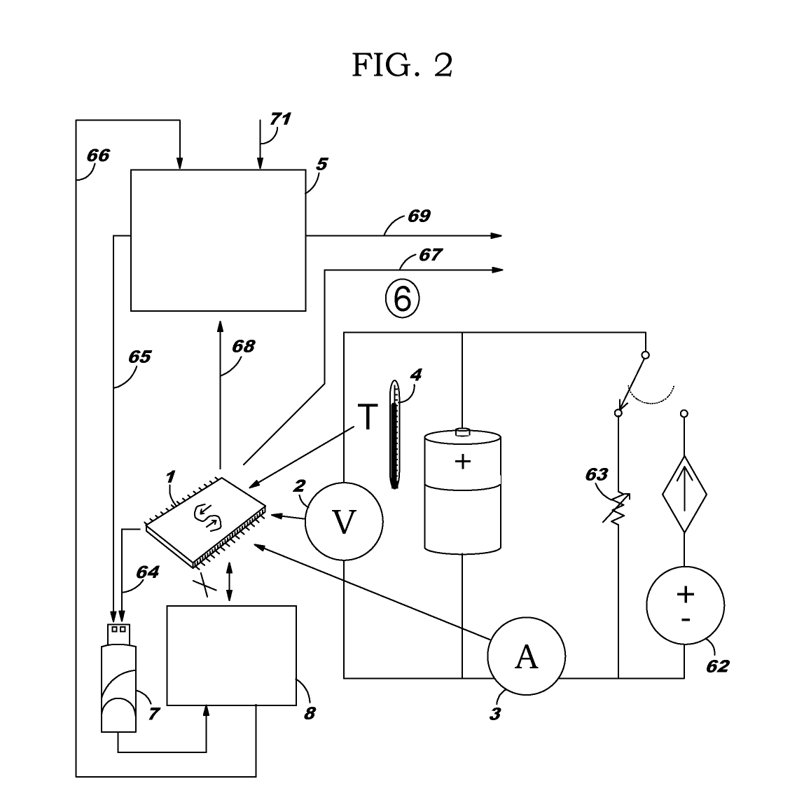

Turning now to FIG. 2, we see the Battery System Manager 1 as before, this time carrying out an adaptive optimization algorithm 8. Recorded data (line 64) along with state estimates produced by the simulator (line 65) are stored in memory 7. The algorithm 8 permits development of optimized model parameters (line 66) to be used in the battery model 5. The battery model 5 also draws upon currently measured real-world data (line 68). The battery model 5 yields for example battery current and future predictions at times T (line 69).

For transient analysis, components are represented in differential or integral form. Non-linear elements are solved by an iterative method (e.g. Newton-Raphson) at each time step. An initial guess at the node voltages is created. The slope and intercept of the tangent to the actual I-V curve is used to calculate a linear approximation of the non-linear element. The linear approximation is used as a proxy for the real-world device. Solution of the linear proxy yields a better guess at the voltage vector. A new set of conductance/current source proxies are calculated using tangents at the new voltages. This is repeated until convergence is reached.

2. Predicting Future States. The system just described has the capability of predicting future states of the battery pack based on load and temperature profiles. The simulation can produce complete waveforms that depict the future voltage variations corresponding to hypothetical dynamic loads and alternating charge/discharge cycles, typical in the car environment, indicated by line 71 in FIG. 2. Such a system can execute “what if” scenarios and provide alternatives to the battery user that can maximize the battery utilization. For example, the system can use a driving pattern to project in the future when cells are going to reach voltages below the cutoff threshold and it can simulate a different driving pattern that instead can maximize the range and provide for both quantitative data so the driver can make the decision. Such projections or predictions are, for example, carried out by branch element 101 in FIG. 3, as discussed above.

3. Estimating the quality of prediction. Since the battery model is emulating all significant operating aspects of the battery, it can provide an estimate of the prediction quality. An example of the way it may work is as follows:
The Battery System Manager 1 samples the battery at discrete times T(n).
At time T(k) for the k-th sample, the battery model 5 produces an a priori state estimate X(k-) which is based on inputs 3 and 4. The a priori state estimate includes as output the battery voltage 2 which is also measured at time T(k).
The comparison between the measured and estimated battery voltage is used to provide an estimate (FIG. 2, line 67) of the accuracy of the simulation module.

Another example is the SOC. SOC is directly related to the Open Circuit Voltage (OCV) of the cells. During periods of time when the battery is idle, the voltage 2 is the OCV of the cells. The same quantity is estimated by the battery simulator. The difference can be used to characterize the divergence between the actual and the simulated values.

4. Adaptive optimization algorithm. Each time the battery is sampled the recorded data (line 64, FIG. 2) along with state estimates produced by the simulator (line 65, FIG. 2) are stored in memory 7. Comparisons between simulated and measured data may then be used to adapt simulation model parameters (line 66, FIG. 2) in order to achieve a closer matching between them. A simple optimization algorithm such as least-squares can be used over an extensive set of past values to ensure better matching between simulated and actual values in the future. The adaptive optimization algorithm 8 can be performed either onboard by the Battery System Manager 1 or data can be offloaded by several BSMs and processed offline. From the whole set of historic data (actual and predicted), selections can be made that provide information useful to estimate specific branch elements of the simulation circuit. For example during DC conditions (discharge or charge under constant current) “resistor” type elements can be estimated. During transients “capacitive” type or “inductor” type of elements can be estimated.

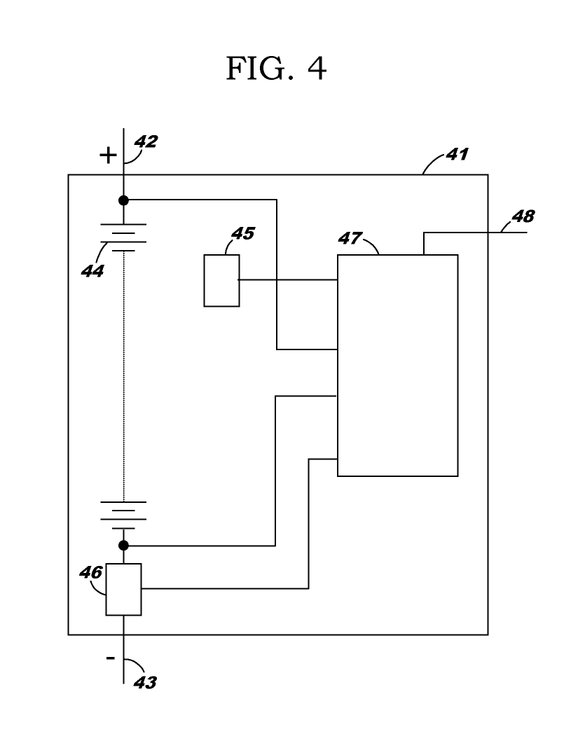

Turning now to FIG. 4, it will be appreciated that the simulation may be carried out by means of electronic circuit 47 constructed for the purpose, thus achieving results much like those of a software-based simulation such as SPICE. Such circuit 47 may be packaged with an actual battery 44 in a real-life usage environment, permitting development of SOC, SOF, and SOH information in real time and with better accuracy than some prior-art approaches. The circuit 47 receives inputs such as battery temperature at 45 and current at 46 as well as two-terminal cell voltage across battery 44. In this example the whole is packaged in package 41, presenting itself to the end user as a two-terminal device with terminals 42, 43 and with a communications bus 48 communicating SOC, SOF, and/or SOH external to the package 41. This arrangement of package 41 thus makes use of the electronic circuit 47 as a battery prediction and monitoring and management tool.

It is thought preferable to package the electronic circuit 47 (implementing the battery management and simulation functions) in the same package 41 as the battery 44, as depicted in FIG. 4. This assures that whenever the battery 44 is swapped out of service (with a different battery installed in its place) then there is no danger that the battery management functions would continue using data relating to the battery 44 that is no longer in service. The historical data and simulation parameters contributing to accurate SOC, SOH, and SOF indications would follow the battery itself. Other approaches could, however, be employed if design constraints required such other approaches.

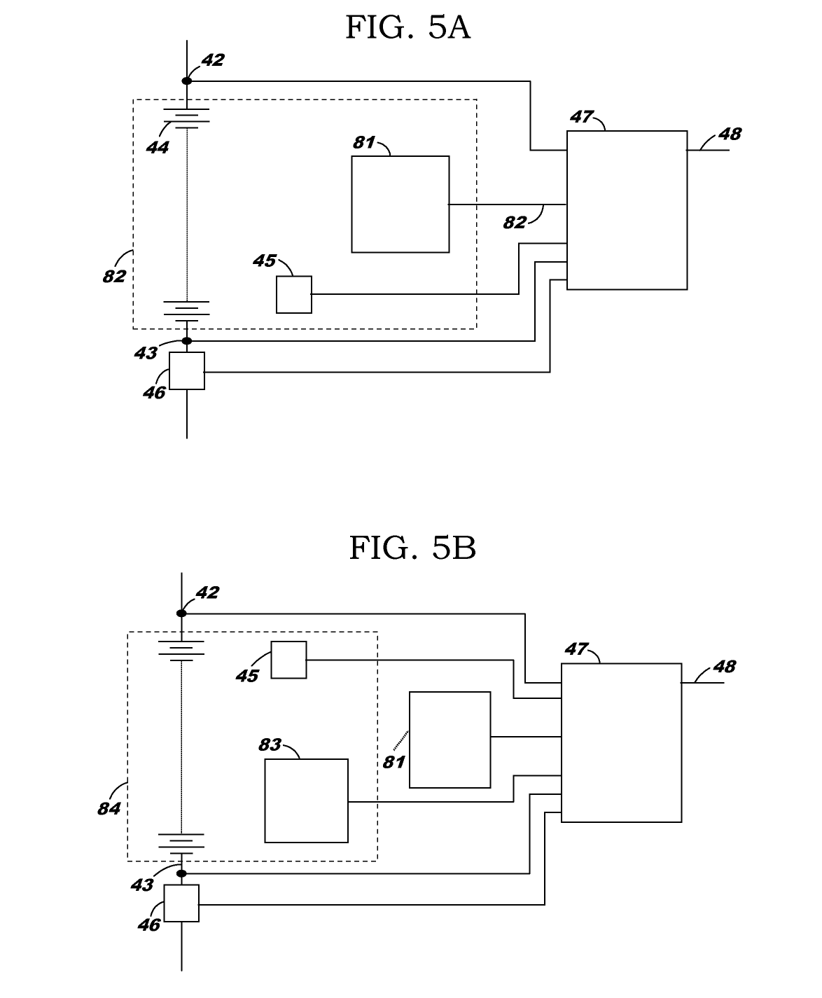

For example the package 82 (FIG. 5a) could contain the battery 44 and a nonvolatile memory 81 which stores historical data and simulation parameters relating to the particular battery 44. The data stored in memory 81 would then be drawn upon by circuit 47 in FIG. 5a, located (in this embodiment) external to the battery 44. Such an approach would be appropriate if there were some design constraint demanded that the circuitry 47 be external to the battery 44. Importantly if the battery package 82 were swapped out, there is no danger of the circuitry 47 mistakenly making use of old data relating to the swapped-out battery when managing the new (swapped-in) battery.

Yet another approach, as shown in FIG. 5b, packages a cryptographic key 83 with the battery, uniquely identifying the particular battery 44. In this approach the circuitry 47 stores the battery-specific data in nonvolatile memory 81. Circuitry 47 checks the cryptographic key 83 from time to time. If the package 84 gets swapped out, the cryptographic key 83 changes, and circuitry 47 knows that the battery-specific data in memory 81 is no longer usable in connection with the swapped-in new battery.

It will be appreciated by the alert reader that myriad obvious variations and improvements may be made to the embodiments set forth above, and that the invention itself is not limited to the particular embodiments above which are merely exemplary. Such variations and improvements are intended to be encompassed by the claims which follow.

1. A method for use with a battery, the method comprising the steps of:
in a battery simulator, defining at least one first node representing a measurable physical value of the battery;
in the battery simulator, defining at least one second node representing a quality of the battery that is desired to be predicted;
in the battery simulator, defining at least one third node;
in the battery simulator, defining at least first and second branch elements, the first branch element connected in the battery simulator to the at least one first node, the first branch element connected in the battery simulator to the at least one second node, the first branch element connected in the battery simulator to the at least one third node, the second branch element connected in the battery simulator to the at least one first node, the second branch element connected in the battery simulator to the at least one second node, the second branch element connected in the battery simulator to the at least one third node;
at least one of the first and second branch elements having at least one output thereof responding non-linearly to at least one input thereof, the output and the input each connected in the battery simulator to a respective node;
the method further comprising communicating information indicative of the quality of the battery that is desired to be predicted to a destination external to the battery.

2. The method of claim 1 wherein the at least one first node representing a measurable physical value of the battery comprises a node representing battery voltage and a node potential represents a value of current.

3. The method of claim 2 wherein the at least one first node representing a measurable physical value of the battery further comprises a node representing battery temperature.

4. The method of claim 1 wherein the at least one second node representing a quality of the battery that is desired to be predicted comprises a node representing one of the set comprising state of charge of the battery, state of health of the battery, and state of function of the battery.

5. The method of claim 1 wherein the battery simulator comprises electronic circuitry.

6. The method of claim 1 wherein the battery simulator comprises a digital computer running SPICE.

7. The method of claim 1 further comprising the steps of:
sampling real-world battery values at a particular time;
using the sampled real-world values as inputs to the at least one first node;
carrying out a circuit simulation with respect to the inputs to the at least one first node, thereby arriving at a prediction of real-world battery values at a later time than the particular time; and
comparing the predicted real-world battery values at the later time with the actual real-world values at the later time, thereby arriving at an estimate of the quality of the prediction.

8. A system comprising:
a battery;
a temperature sensor at said battery yielding a temperature signal;
a current sensor at said battery yielding a current signal;
a battery manager receiving the temperature signal and the current signal and measuring a voltage across the battery, the battery manager comprising a battery simulator;
the battery simulator defining at least one first node representing a measurable physical value of the battery;
the battery simulator defining at least one second node representing a quality of the battery that is desired to be predicted;
the battery simulator defining at least one third node;
the battery simulator further defining at least first and second branch elements, the first branch element connected in the battery simulator to the at least one first node, the first branch element connected in the battery simulator to the at least one second node, the first branch element connected in the battery simulator to the at least one third node, the second branch element connected in the battery simulator to the at least one first node, the second branch element connected in the battery simulator to the at least one second node, the second branch element connected in the battery simulator to the at least one third node,
at least one of the first and second branch elements having at least one output thereof responding non-linearly to at least one input thereof, the output and the input each connected in the battery simulator to a respective node;
the battery manager having a communications channel communicating information indicative of the quality of the battery that is desired to be predicted to a destination external to the battery manager.

9. The system of claim 8 wherein the battery and the battery manager are contained within a housing, the housing having first and second terminals permitting connection of the battery to circuitry external to the housing, the housing further providing the communications channel external to the housing.

10. The system of claim 8 wherein the battery simulator comprises electronic circuitry effecting the first and second branch elements and effecting the at least first and second and third nodes.

11. The system of claim 8 further comprising a nonvolatile memory, wherein the battery and the nonvolatile memory are contained within a housing, the housing having first and second terminals permitting connection of the battery to circuitry external to the housing, the battery manager communicatively coupled with the nonvolatile memory, the battery manager storing battery-specific information in the nonvolatile memory.
